(19) United States
(12) Patent Application Publication
(10) Pub. No.: US 2010/0059896 A1
(43) Pub. Date: Mar. 11, 2010

(54) Coplaner waveguide and fabrication method thereof

(75) Inventors: Takeshi Makita, Tokyo (JP); Isao Tamai, Tokyo (JP); Shinichi Hoshi, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/461,610

(22) Filed: Aug. 18, 2009

(30) Foreign Application Priority Data
Sep. 11, 2008 (JP) 2008-233399

(51) Int. Cl. H01L 23/52; H01L 21/768

(52) U.S. Cl. 257/775; 438/666; 257/E23.141; 257/E21.575

(57) ABSTRACT

A coplanar waveguide includes a substrate, a signal line formed on the substrate, a pair of ground conductors formed on the substrate on mutually opposite sides of the signal line, a signal line insulating film disposed between the signal line and the substrate, and a ground conductor insulating film disposed between the pair of ground conductors and the substrate. No corresponding insulating film is present on the substrate between the signal line and the ground conductors. Even if a silicon substrate is used, the attenuation characteristics of the coplanar waveguide are comparable to the attenuation characteristics of coplanar waveguides formed on compound semiconductor substrates.

### BACKGROUND OF THE INVENTION

1. Field of the Invention

The present invention relates to a coplanar waveguide used for interconnecting integrated circuit elements operating in the millimeter-wave frequency band or connecting such circuit elements to package connectors, and to a coplanar waveguide fabrication method.

2. Description of the Related Art

In a monolithic microwave integrated circuit (MMIC) with active elements such as mixers and amplifiers and passive elements such as filters and capacitors, coplanar waveguides are used to interconnect the active and passive elements. Such coplanar waveguides generally comprise metal wiring patterns, and the substrate is generally a compound semiconductor substrate such as a gallium arsenide (GaAs) or indium phosphide (InP) substrate. One advantage of a compound semiconductor substrate is that its high electron mobility permits the formation of MMICs that can operate in the ten-gigahertz (10-GHz) band or higher. Another advantage is that it is easy to fabricate compound semiconductor substrates having a resistivity as high as about ten million ohm-centimeters (107 Ω·cm).

Monocrystalline compound semiconductor substrates are, however, more expensive than monocrystalline silicon (Si) semiconductor substrates. Moreover, commercially available monocrystalline compound semiconductor wafers are generally only three to four inches in diameter, whereas ten-inch monocrystalline silicon semiconductor wafers are readily available. Because of the high cost and small size of monocrystalline compound semiconductor wafers, MMICs formed on monocrystalline compound semiconductor substrates are expensive.

In Japanese Patent Application Publication No. 2000-068714, Matsumoto has described the formation of coplanar waveguides in which the signal line and ground conductors are both disposed on an insulating film such as a silicon oxide film, a silicon nitride film, or a polyimide film at least ten micrometers (10 μm) thick, formed on a monocrystalline silicon semiconductor substrate with a resistivity of one thousand to ten thousand ohm-centimeters (1 kΩ·cm to 10 kΩ·cm). The insulating film reduces leakage of electromagnetic wave energy into the substrate, so that an MMIC with coplanar waveguides of this type can operate at frequencies in excess of 10 GHz despite the use of a silicon substrate.

When a silicon oxide or silicon nitride film at least 10 μm thick is formed by use of plasma chemical vapor deposition (CVD) apparatus available to the inventor, however, the growth rates of the silicon oxide and silicon nitride films are 40 nanometers per minute (nm/min) and 14 nm/min, respectively. Accordingly, forming insulating films of these materials 10 μm thick takes about 250 minutes and 720 minutes, respectively, which is impractical for commercial fabrication.

It is possible to increase the growth rate by changing the film formation conditions. This, however, requires measures to be taken to prevent degradation of film quality. Increasing the film thickness also causes warping of the wafer, so that care must be taken to prevent development faults in subsequent photolithography processes.

If a spin coatable film material such as polyimide is used, spin-coaters that can form films 2 μm to 8 μm thick are commercially available. A polyimide insulating film, however, requires additional processes, such as a surface treatment process for increasing metal adhesion strength. These additional processes differ from ordinary semiconductor processes and lead to increased fabrication cost. Moreover, the film materials used by commercially available spin coaters do not readily yield films with thicknesses of 10 μm or more in one coating; two or more coating processes are required. A baking process with a baking time of thirty minutes to one hour is necessary after each coating process, leading to an increase in fabrication time. In addition, cracks may occur in the film in the second coating process.

### SUMMARY OF THE INVENTION

An object of the present invention is to provide a coplanar waveguide that can carry millimeter-wave signals on a monocrystalline silicon semiconductor substrate without the need for an insulating film having a thickness of 10 μm or more.

A coplanar waveguide according to the present invention accordingly includes a substrate, a signal line formed on the substrate, a pair of ground conductors formed on a major surface of the substrate on mutually opposite sides of the signal line, a signal line insulating film disposed between the signal line and the substrate, and a ground conductor insulating film disposed between the pair of ground conductors and the substrate. The signal line insulating film and ground conductor insulating film are preferably 200 nm to 2 μm thick, and are preferably formed of silicon oxide, silicon nitride, or silicon oxynitride. These films may also have a stacked structure including a silicon oxide film and a silicon nitride film, or a silicon oxynitride film and a silicon nitride film. The substrate is preferably a high-resistivity silicon substrate with a resistivity greater than 100 Ω·cm. The coplanar waveguide may also include trenches formed in the major surface of the substrate between the signal line and the ground conductors and at least one conductive bridge interconnecting the pair of ground conductors by passing over the signal line. The trenches are preferably at least 200 nm deep.

A method of fabricating a coplanar waveguide according to the present invention includes forming an insulating film on a major surface of a substrate, forming a signal line and a pair of ground conductors on the insulating film, the signal line being formed between the ground conductors, and removing the insulating film between the signal line and the ground conductors by using the signal line and the ground conductors as a mask. The insulating film preferably has a thickness of 200 nm to 2 μm, and is preferably formed of silicon oxide, silicon nitride, or silicon oxynitride. The insulating film may also be formed as a stacked structure including a silicon oxide film and a silicon nitride film, or a silicon oxynitride film and a silicon nitride film. The substrate is preferably a high-resistivity silicon substrate with a resistivity exceeding 100 Ω·cm. After the insulating film is removed from between the signal line and the ground conductors, trenches, preferably at least 200 nm deep, may be formed on the major surface of the substrate between the signal line and the ground conductors. In addition, conductive bridges may be formed that interconnect the pair of ground conductors by passing over the signal line.

When an insulating film is formed on a high-resistivity silicon substrate, a low-resistivity layer forms in the neighborhood of the interface between the silicon substrate and the insulating film, but in the present invention the insulating film is removed from the regions between the signal line and the ground conductors, so the low-resistivity layer disappears in these regions.

The signal line insulating film and ground conductor insulating film therefore need only be thick enough to insulate the signal line and ground conductors from the substrate and can be as thin as, for example, about 200 nm. As a result, the insulating film can be formed by conventional plasma CVD, making the coplanar waveguides inexpensive and easy to fabricate.

### BRIEF DESCRIPTION OF THE DRAWINGS

In the attached drawings:

FIGS. 1, 2, and 3 are sectional views of coplanar waveguides embodying the present invention;

FIGS. 4 to 8 are sectional views illustrating a process for fabricating the coplanar waveguide in FIG. 1;

FIGS. 9 to 14 are sectional views illustrating further process steps for fabricating the coplanar waveguides in FIGS. 2 and 3;

FIG. 15 is a plan view of a coplanar waveguide;

FIG. 16 shows a test setup for evaluating the coplanar waveguide in FIG. 15;

FIG. 17 is a graph illustrating the frequency dependency of the attenuation constant of coplanar waveguides formed on Si and InP substrates with various resistivities;

FIG. 18 shows an equivalent circuit of a coplanar waveguide;

FIG. 19 shows part of the equivalent circuit in FIG. 18;

FIG. 20 is a perspective view of a metal rectangular solid model;

FIGS. 21 and 22 illustrate the design of a coplanar waveguide by conformal mapping;

FIG. 23 shows an equivalent circuit of a distributed constant circuit;

FIG. 24 is a graph illustrating the calculated frequency dependency of the attenuation constant of coplanar waveguides formed on Si and InP substrates with various resistivities;

FIG. 25 is a graph illustrating the measured frequency dependency of the attenuation constant of three of the coplanar waveguides in FIG. 24;

FIG. 26 shows an equivalent circuit of a coplanar waveguide with a low-resistivity layer; and

FIGS. 27 and 28 are graphs illustrating the calculated frequency dependency of the attenuation constant of coplanar waveguides with a low-resistivity layer.

### DETAILED DESCRIPTION OF THE INVENTION

The invention will now be described in more detail with reference to the attached non-limiting drawings, in which like elements are indicated by like reference characters. Reference characters 20 and 22 will be used to denote flat and trenched substrates, respectively.

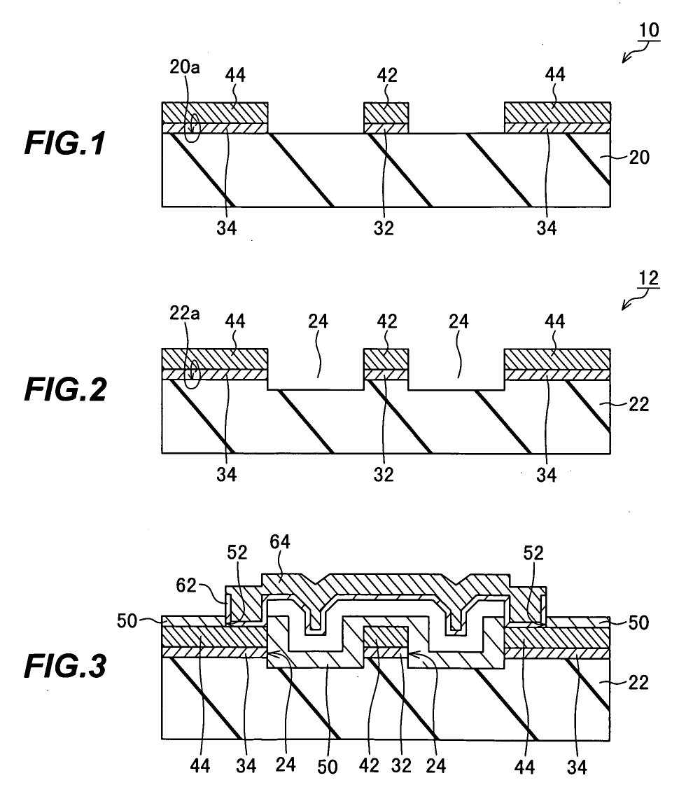

Referring to FIG. 1, a first coplanar waveguide 10 embodying the invention comprises a flat substrate 20, a signal line 42 formed on the substrate 20, and a pair of ground conductors 44 disposed on mutually opposite sides of the signal line 42. The signal line 42 and ground conductors 44 are insulated from the substrate 20 by insulating films formed on a major surface 20a of the substrate 20. The insulating film interposed between the substrate 20 and the signal line 42 is referred to as the signal line insulating film 32; the insulating film interposed between the substrate 20 and the ground conductors 44 is separate from the signal line insulating film 32 and is referred to as the ground conductor insulating film 34. There is no insulating film in the region between the signal line 42 and the ground conductors 44.

The substrate 20 is a high-resistivity monocrystalline silicon substrate with a resistivity of at least 1 kΩ·cm, although not exceeding 10 kΩ·cm.

The insulating films 32, 34 are, for example, silicon oxide (SiO₂) films, silicon nitride (SiN) films, or silicon oxynitride (SiON) films, all of which can be formed by conventional methods such as, for example, plasma CVD.

The insulating films 32, 34 need be only thick enough to insulate the signal line 42 and ground conductors 44 from the substrate 20. The insulating films 32, 34 are preferably at least 200 nm thick, but as their thickness increases, stress effects become significant, so the thickness preferably does not exceed 2 μm.

When the insulating films 32, 34 are formed of SiO₂ or SiON, a stacked structure, in which an SiN film is formed on the SiO₂ film or SiON film, is preferable in order to increase the adhesion between the insulating films and the signal line and ground conductors.

Referring to FIG. 2, a second coplanar waveguide 12 embodying the invention is generally similar to the coplanar waveguide 10 in FIG. 1, but a pair of trenches 24 are formed in the major surface 22a of the substrate 22 in the areas between the signal line 42 and the ground conductors 44 that are not covered by the signal line insulating film 32. The trenches 24 should be at least 200 nm deep. The reason for forming the trenches 24 is associated with air bridges, which are generally formed in coplanar waveguides at intervals of about one quarter of the wavelength of the propagating electromagnetic wave to equalize the potentials of the ground conductors.

To form the air bridges, a passivation film is formed in the areas between the signal line 42 and the ground conductors 44 that are not covered by the insulating film. If the passivation film is an SiO₂ film or an SiON film, a low-resistivity layer forms at the interface between the passivation film and the substrate and increases leakage of electromagnetic wave energy into the substrate. In the structure shown in FIG. 2, however, the distance between the low-resistivity layer and the signal line 42 is increased by an amount equal to the depth of the trenches 24. If the trenches 24 are at least 200 nm deep the adverse effects of the low-resistivity layer can be avoided.

FIG. 3 shows the air bridge structure. The coplanar waveguide includes a passivation film 50 that covers the upper and side surfaces of the signal line 42 and ground conductors 44, the side surfaces of the signal line insulating film 32 and ground conductor insulating films 34, and the lower and side surfaces of the trenches 24 formed in the substrate 22.

The passivation film 50 has openings 52 exposing parts of the pair of ground conductors 44. The ground conductors 44 are electrically interconnected by a metal structure to form an air bridge. The metal interconnection comprises a suitable metal layer 64 plated onto a current film 62. The current film 62 may include, for example, a 50-nm titanium (Ti) film and a 100-nm gold (Au) film.

Next a method of fabricating the coplanar waveguide in FIG. 1 will be described with reference to FIGS. 4 to 8.

Referring to FIG. 4, first a high-resistivity silicon substrate 20 is prepared. The resistivity of the substrate 20 should be greater than 100 Ω·cm and is preferably from 1 kΩ·cm to 10 kΩ·cm. The substrate 20 is cleaned by a conventional method to remove its natural oxide film.

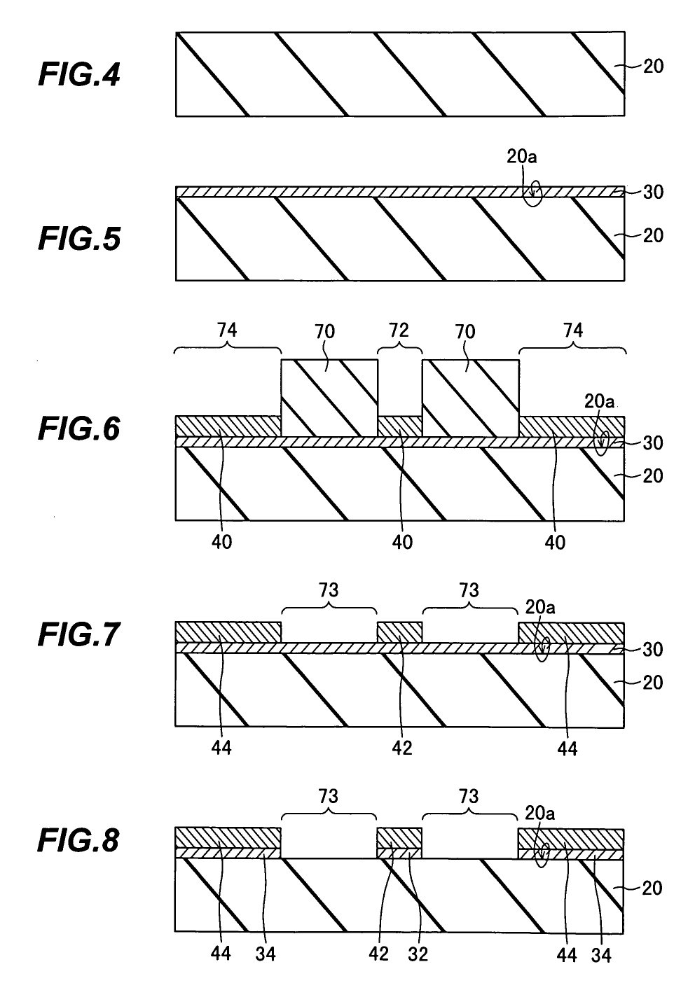

Referring to FIG. 5, next an insulating film 30 is formed on the major surface 20a of the substrate 20. The insulating film 30 is an SiO₂ film, an SiN film, or an SiON film formed by, for example, conventional plasma CVD or thermal CVD. The thickness of the insulating film 30 is at least 200 nm but is not more than 2 μm, for the reasons given above.

As noted above, if an SiO₂ film or an SiON film is used, the insulating film 30 preferably has a stacked structure in which a very thin SiN film about 20 nm thick is formed on the SiO₂ film or SiON film.

Next the signal line and ground conductors are formed on the insulating film 30 by conventional photolithography, deposition, and etching processes as follows.

First a resist is applied to the surface of the insulating film 30, exposed to light through a mask, and developed to form the resist pattern 70 shown in FIG. 6. The development process removes the resist from a region 72 where the signal line will be formed and from regions 74 on both sides of region 72, where the ground conductors will be formed. Next a metal film 40 such as, for example, a gold (Au) film is formed in these regions 72, 74 by evaporation deposition or plating.

The resist pattern 70 is then removed by using, for example, an organic solvent, leaving the signal line 42 and the ground conductors 44 as shown in FIG. 7.

Referring to FIG. 8, after formation of the signal line 42 and ground conductors 44, etching is performed, using the signal line 42 and ground conductors 44 as a mask, to remove the insulating film 30 from the regions 73 between the signal line 42 and the ground conductors 44. This process may be carried out by, for example, reactive ion etching (RIE) using silicon hexafluoride (SF₆) or carbon tetrafluoride (CF₄) gas. Since SF₆ gas and CF₄ gas do not react with metals, the signal line 42 and the ground conductors 44 formed in the preceding deposition steps do not need to be protected by an additional mask. Alternatively, the insulating film 30 may be etched by wet etching.

This etching process may be allowed to over-etch the insulating film 30, so that parts of the substrate 20 are also etched to form the trenches on the major surface of the substrate 20.

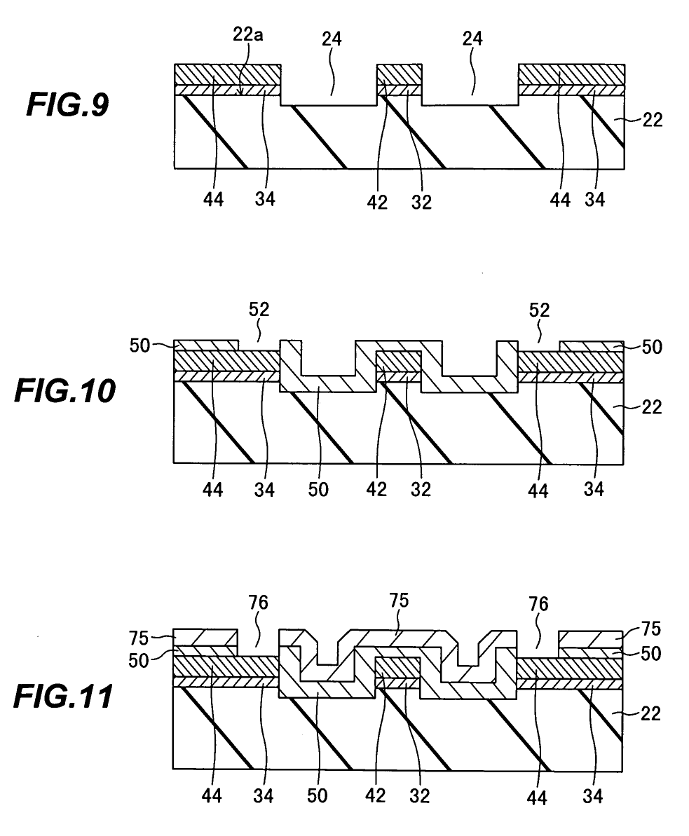

A method of fabricating an air bridge structure will now be described with reference to FIGS. 9 to 14. The air bridge fabrication process is performed after the coplanar waveguide fabrication process described in FIGS. 4 to 8.

During or after the formation of the coplanar waveguide shown in FIG. 8, the substrate 20 is over-etched to form trenches 24 on the major surface 22a of the substrate 22 as shown in FIG. 9. The trenches 24 should be at least 200 nm deep.

Referring to FIG. 10, next a passivation film 50 is formed on the coplanar waveguide by, for example, conventional plasma CVD or thermal CVD. The passivation film 50 is an SiO₂ film or SiN film approximately 200 nm thick. Openings 52 are formed in the passivation film 50 over parts of the ground conductors 44 by conventional photolithography and etching processes.

Referring to FIG. 11, next an air bridge resist pattern 75 is formed on the passivation film 50. The air bridge resist pattern 75 has openings 76 at the positions of the openings 52 formed in the passivation film 50.

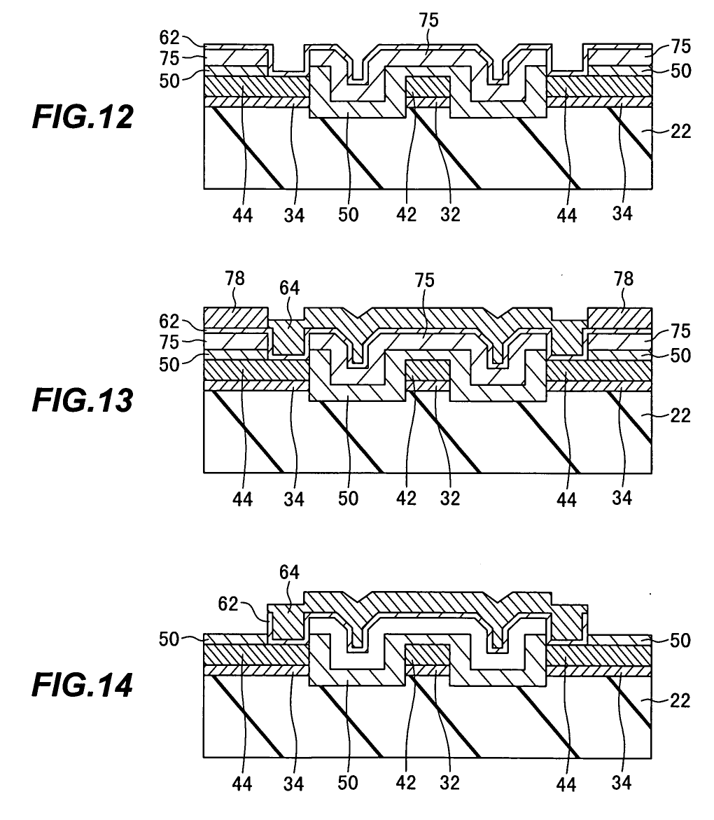

Referring to FIG. 12, next a current film 62 is formed on the air bridge resist pattern 75. The current film 62 includes a 50-nm titanium (Ti) layer and a 100-nm gold (Au) layer.

Referring to FIG. 13, next a plating resist pattern 78 is formed. The plating resist pattern 78 is formed so as to expose the regions in which air bridge interconnections will be formed, and cover other regions. After the formation of the plating resist pattern 78, gold plating, for example, is performed on the current film 62 exposed by the plating resist pattern 78, thereby forming a metal layer 64 and obtaining the desired air bridge interconnections.

Referring to FIG. 14, the plating resist pattern 78, the part of the current film 62 on which the air bridge interconnections are not formed, and the air bridge resist pattern 75 are sequentially removed to obtain an air bridge structure with an air gap between the metal layer 64 and the passivation film 50 covering the signal line 42.

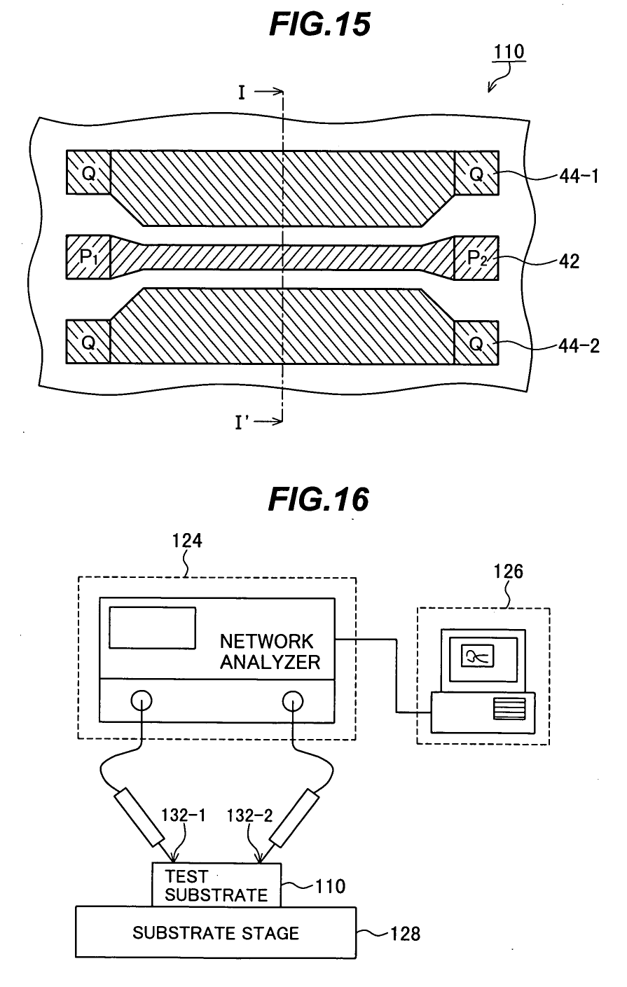

A method of evaluating the coplanar waveguide will be described with reference to FIGS. 15 and 16. In the plan view in FIG. 15, conductive elements are indicated by hatching. FIG. 1 corresponds to a cross section taken through line I-I′ in FIG. 15.

The coplanar waveguide pattern in FIG. 15 is disposed on a substrate surface and includes the signal line 42 and the ground conductors 44-1, 44-2. At the two ends of the signal line 42, electrode pads are formed as a first port P₁ and a second port P₂. Similarly, electrode pads are formed as ground ports Q at both ends of each of the ground conductors 44-1, 44-2.

In the exemplary configuration shown in FIG. 15, the signal line 42 and the facing sides of the pair of ground conductors 44-1, 44-2 are mutually parallel. The two ground conductors 44-1, 44-2 are equally distant from the signal line 42. The pattern is symmetrical about the longitudinal axis of the signal line 42.

The scattering parameters or S-parameters of this coplanar waveguide configuration can be measured with the test setup shown in FIG. 16, comprising a network analyzer 124, a personal computer 126, a substrate stage 128, and probes 132-1, 132-2. A test substrate 110 on which the coplanar waveguide is formed is mounted on the stage 128. The ground ports Q at both ends of the ground conductors 44-1, 44-2 and the first and second ports P₁, P₂ of the signal line 42 are connected to the network analyzer 124 through the probes 132-1, 132-2, which have a conventional coplanar structure with three electrodes each. Probe 132-1 in FIG. 16 makes contact with the three electrode pads Q, P₁, Q on the left side in FIG. 15; probe 132-2 makes contact with the three electrode pads Q, P₂, Q on the right side in FIG. 15.

Air coplanar probes available from Cascade Microtech Inc. of Beaverton, Oreg., for example, may be used as the probes 132-1, 132-2. The network analyzer should be selected according to the required measurement frequency band. Suitable network analyzers can be obtained from Agilent Technologies Inc. of Santa Clara, Calif., Anritsu Corp. of Atsugi, Japan, and other sources.

The S-matrix is used to indicate small signal characteristics at high frequencies. The matrix elements or S-parameters are expressed as power ratios of transmission and reflection signal components with respect to an input signal and can be measured even in high frequency bands. The S-matrix is a matrix with two rows and two columns, defined by the following equation (1).

$$( \begin{matrix}{b}_{1} \\ {b}_{2}\end{matrix} ) = ( \begin{matrix}{S}_{11} {S}_{12} \\ {S}_{21} {S}_{22}\end{matrix} ) ( \begin{matrix}{a}_{1} \\ {a}_{2}\end{matrix} ) \qquad ( 1 )$$

In the above equation, a₁ and a₂ are column vector elements representing the power of the input signals and b₁ and b₂ are column vector elements representing the power of the output signals.

When the two ends of the signal line 42 are defined as the first and second ports P₁, P₂, respectively, an input signal a₁ is input to the first port P₁ and the reflection signal b₁ output from the first port P₁ and the transmission signal b₂ output from the second port P₂ are measured. From these measurements, the reflection and transmission coefficients for the input signal a₁ input to the first port P₁ are obtained and used as S-matrix elements S₁₁ and S₂₁. Similarly, an input signal a₂ is input to the second port P₂ and the reflection signal b₂ output from the second port P₂ and the transmission signal b₁ output from the first port P₁ are measured. From these measurements, the reflection and transmission coefficients for the input signal a₂ input to the second port P₂ are obtained and used as S-matrix elements S₂₂ and S₁₂. The S-matrix of the coplanar waveguide is thereby determined.

Accordingly, S-matrix elements S₁₁ and S₂₂ represent the reflection coefficients observed at the first and second ports P₁ and P₂, respectively; S-matrix elements S₁₂ and S₂₁ represent the transmission coefficients from the first port P₁ to the second port P₂ and from the second port P₂ to the first port P₁, respectively.

As the coplanar waveguide pattern in FIG. 15 is symmetrical with respect to the first and second ports P₁, P₂, if measurement error and environmental effects are ignored, S₁₁ should be equal to S₂₂ (S₁₁=S22) and S₁₂ should be equal to S₂₁ (S₁₂=S₂₁). Environmental effects include factors such as temperature changes and electrical noise.

The S-parameters are measured with a small input signal having a frequency in the required frequency band. An attenuation constant αₘ is calculated from the measured S₂₁ (or S₁₂) S-parameter by the following equation (2).

$${α}_{m} = - 20 \cdot \frac{log ( \vert {S}_{21} \vert )}{H} \qquad ( 2 )$$

In the above equation, H is the distance between the two ends of the signal line forming the coplanar waveguide (the distance from the first port P₁ to the second port P₂) and corresponds to the length of the transmission line.

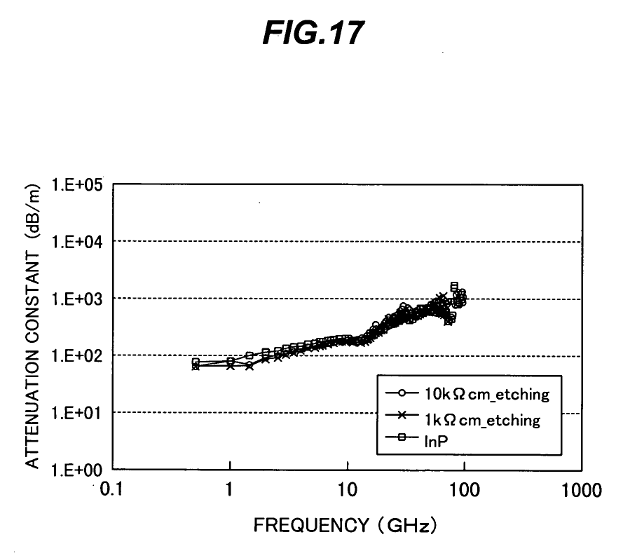

Attenuation constants obtained by the above procedure are shown in FIG. 17, in which the horizontal axis represents frequency in GHz and the vertical axis represents the attenuation constant αₘ in decibels per meter (dB/m). Measurement results obtained from coplanar waveguides formed on silicon substrates having resistivities of 10 kΩ·cm and 1 kΩ·cm according to the present invention (FIG. 1) are indicated by white circles and cross marks, respectively. For comparison, measurement results obtained from a coplanar waveguide formed on an InP substrate are indicated by white squares.

The results shown in FIG. 17 indicate that even though the coplanar waveguides structured according to the present invention are formed on silicon substrates, they have substantially the same attenuation constant as would be obtained by use of a more expensive compound semiconductor substrate.

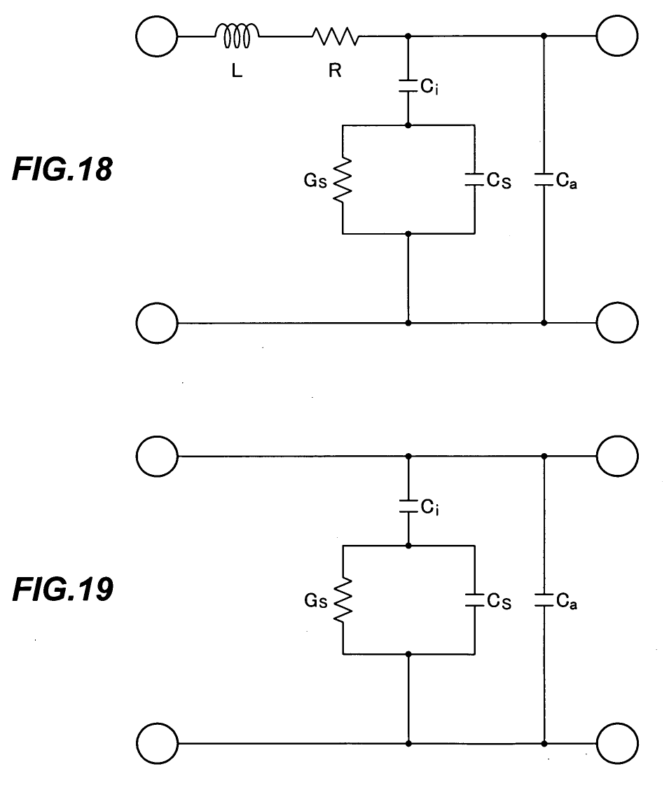

A coplanar waveguide according to the present invention may be modeled by an equivalent circuit as shown in FIGS. 18 and 19, in which an equivalent signal line is shown at the top and an equivalent ground conductor is shown at the bottom.

The elements L and R shown in FIG. 18 are the inductance and resistance, respectively, per unit length of the signal line 42. The element Cᵢ is the capacitance of the signal line insulating film per unit length of the coplanar waveguide. The elements Cₛ and Gₛ are the capacitance and conductance, respectively, of the substrate per unit length of the coplanar waveguide. The element Cₐ is the capacitance of the air above the coplanar waveguide, per unit length of the coplanar waveguide. The unit length is one meter (1 m) In the following description, c₀ is the speed of light in a vacuum, ε₀ is the permittivity of the vacuum, εᵣ is the relative permittivity of the substrate, and εᵢ is the relative permittivity of the insulating film.

The resistance R of the signal line 42 can be calculated from the material and shape of the signal line. If, for example, the signal line has width w and thickness d and the conductive metal constituting the signal line has resistivity p, the resistance R of the signal line per unit length is given by the following equation (3).

$$R = ρ \frac{1}{wd} . \qquad ( 3 )$$

When the S-parameters are obtained in a frequency band where a skin effect appears, the value of the resistance R is calculated according to the following procedure. The skin effect appears when a high-frequency signal is transmitted through a conductor such as a thin metal film: the current density of the signal is highest at the surface of the conductor and becomes lower with increasing distance from the surface. The current becomes increasingly concentrated toward the surface of the conductor as the frequency increases. Because of the skin effect, the apparent AC resistance of the conductor increases as the frequency increases.

If the skin depth is defined as the distance δ at which the electromagnetic field intensity is attenuated to a value equal to 1/e times the value at the surface of the thin metal film, where e is the base value of the natural logarithms, the skin depth is given by the following equation (4).

$$δ = \sqrt{\frac{2}{ω μσ}} \qquad ( 4 )$$

In the above equation, σ is the conductance of the conductive metal; ω is the angular frequency of the signal; μ is the permeability of the conductive metal and is generally equal to the permeability μ₀ of the vacuum.

It is assumed here that the width w of the signal line 42 is greater than the thickness d of the signal line 42 (w>d). The width w is the dimension of the signal line 42 in the direction perpendicular to the longitudinal direction of the signal line 42 and parallel to the surface of the substrate 20. The thickness d is the dimension in the direction perpendicular to the surface of the substrate 20. The thickness d of a metal film formed by evaporation is generally on the order of 100 nm, whereas the width w of the signal line 42 is generally on the order of several micrometers or several tens of micrometers, so the above assumption (w>d) is normally satisfied by a wide margin.

The skin effect becomes significant at an angular frequency ω that makes the distance δ less than or equal to d/2. This frequency f is given by the following equation (5), which is derived by substituting the relationships δ=d/2 and ω=2πf into the above equation (4).

$$f = \frac{4}{π μσ {d}^{2}} \qquad ( 5 )$$

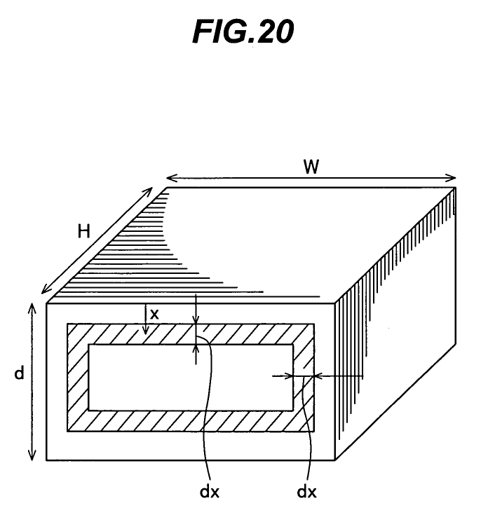

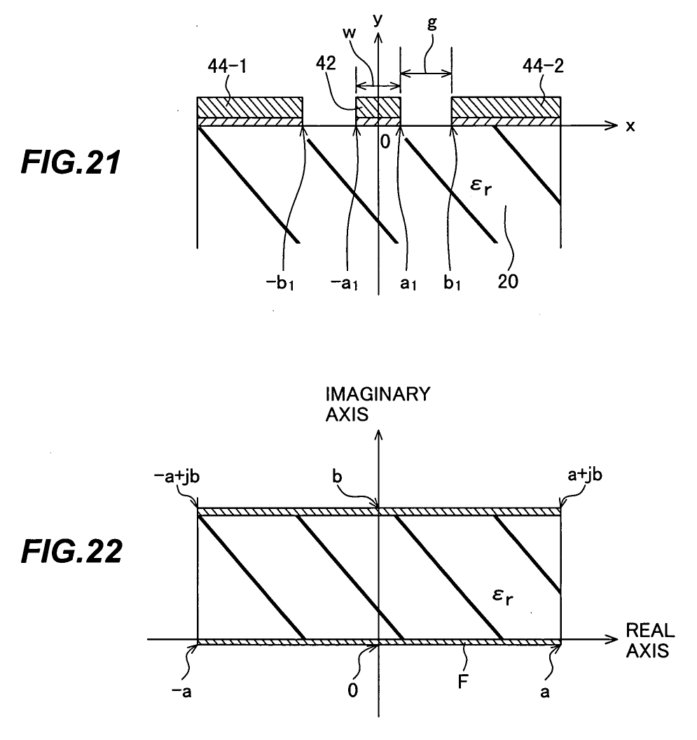

The resistance value including the skin effect will now be obtained with reference to FIG. 20, in which the signal line is modeled as a rectangular metal solid of height d, width w (w>d), and length H. This metal rectangular solid can be regarded as a representative part of a thin metal film signal line, preferably a thin gold film signal line, through which a signal propagates.

The conductance dG of the hatched region in FIG. 20, consisting of material from distance x to distance x+dx from the surface, is given by the following equation (6), in which the two-dimensional area of the hatched region is regarded as equal to dx×2{(w−2x)+(d−2x)}.

$$dG = σ \cdot exp ( - \frac{x}{δ} ) \cdot \frac{2 \{ ( w - 2 x ) + ( d - 2 x ) \} dx}{H} \qquad ( 6 )$$

If this equation is integrated with respect to x from 0 to d/2 and the reciprocal of the result is taken, the resistance value R (=1/G) of this conductive line is obtained as in the following equation (7).

$$R = \frac{H}{2 σ δ \{ w + d - 4 δ + ( d - w + 4 δ ) exp ( - \frac{d}{2 δ} ) \}} \qquad ( 7 )$$

The calculation results described above can be summarized by the following equations (8-1), (8-2).

$$\begin{matrix}If f < \frac{4}{π μ σ {d}^{2}} \\ then R = ρ \frac{1}{wd} \\ and if f \geq \frac{4}{π μ σ {d}^{2}} & ( 8 \text{-} 1 ) \\ then R = \frac{1}{2 σ δ \{ w + d - 4 δ + ( d - w + 4 δ ) exp ( - \frac{d}{2 δ} ) \}} & ( 8 \text{-} 2 )\end{matrix}$$

In equations (8-1) and (8-2), the resistance value R shows a discontinuity at the frequency f having a value of 4/(πμσd²). In practice, however, there is no problem with assuming that the resistance value R is given by equation (8-2) for all values of the frequency f.

The values per unit length of the capacitance Cₛ and conductance Gₛ of the substrate with respect to the coplanar waveguide can be obtained by the conformal mapping design method described by Wen in ‘Coplanar Waveguide: A Surface Strip Transmission Line Suitable for Nonreciprocal Gyromagnetic Device Applications’, IEEE Transactions on Microwave Theory and Techniques, Vol. MTT-17, No. 12, pp. 1087-1090 (1969).

The values of the capacitance Cₛ and conductance Gₛ will be obtained with reference to FIGS. 21 and 22. FIG. 21 shows a cross section similar to FIG. 1, in a plane perpendicular to the major surface of the substrate 20 and to the longitudinal direction of the signal line. FIG. 22 shows a conformal mapping of the coplanar waveguide.

In FIG. 21, the axis of symmetry in the width direction of the signal line 42 is set as an origin O, the x-axis is defined as being on the surface of the substrate 20 and extending in the width direction of the signal line 42, and the y-axis is defined as being perpendicular to the x-axis and to the substrate 20. If the x-coordinates at the two edges of the signal line 42 are −a₁ and a₁, the width w of the signal line 42 is 2×a₁. If the x-coordinates of the edges of the ground conductors 44-1, 44-2 on the sides facing the signal line 42 are −b₁ and b₁, respectively, the distance g from the signal line 42 to the ground conductors 44-1, 44-2 is the difference (b₁−a₁) between a₁ and b₁.

If the substrate 20 is regarded as a half-plane extending to infinity in the negative y-axis direction, then as explained by Wen, conformal mapping of the coplanar waveguide in FIG. 21 produces the mapping shown in FIG. 22, in which the semi-infinite dielectric substrate 20 is mapped onto a rectangle having four vertices (−a+jb), (a+jb), (−a), (a) on a complex plane or z-plane with real and imaginary axes.

The signal line 42 and the ground conductors 44-1, 44-2 are mapped onto the upper and lower sides of this rectangle, which have length 2a. The distance g from the signal line 42 to the ground conductors 44-1, 44-2 is converted by the mapping to the length b of the left and right sides of the rectangle.

This mapping makes it possible to calculate the capacitance of the capacitive structure formed by the conductors, the substrate, and the peripheral voids, all of which constitute the coplanar waveguide.

Although the specific values of a and b in the conformal mapping are indeterminate, the ratio (a/b) of a to b can be obtained from a formula given by Wen. The capacitance of the coplanar waveguide includes a component Cₛ due to the substrate and a component Cₐ due to air, as noted above. The values of these capacitive components Cₛ and Cₐ are given in terms of the above ratio (a/b) by the following equations (9-1) and (9-2), in which εᵣ is again the relative permittivity of the substrate 20 and ε₀ is the permittivity of the vacuum.

$$\begin{matrix}{C}_{s} = 2 {ɛ}_{r} {ɛ}_{0} \frac{a}{b} & ( 9 \text{-} 1 ) \\ {C}_{a} = 2 {ɛ}_{0} \frac{a}{b} & ( 9 \text{-} 2 )\end{matrix}$$

The total capacitance C of the coplanar waveguide is the sum of these two components (C=Cₛ+Cₐ).

The phase velocity vₚ of an electromagnetic wave propagating along the coplanar waveguide is given by the following equation (10), in which c₀ is the speed of light in a vacuum.

$${v}_{p} = \sqrt{\frac{2}{{ɛ}_{r} + 1}} {c}_{0} \qquad ( 10 )$$

Accordingly, the overall characteristic impedance Z₀ of the coplanar waveguide is given by the following equation (11).

$${Z}_{0} = \frac{1}{{Cv}_{p}} \qquad ( 11 )$$

Since the characteristic impedance is typically set to 50 Ω in wireless communication systems, the coplanar waveguide may be designed so that the characteristic impedance value given by equation (11) is 50 Ω.

To summarize the above description, the inductance L of the signal line 42 is obtained by the following equation (12).

L=C·Z₀² (12)

Finally, the conductance Gₛ is a parameter relating to dielectric loss. Crystalline substrate suppliers provide information about crystalline substrates including the conductance σ₀ or resistivity ρ₀ for a DC signal. Using the conformal mapping design method described by Wen, the conductance Gₛ for a DC signal flowing through the coplanar waveguide formed on a crystalline substrate is obtained from the equation Gₛ=σ₀×(a/b)

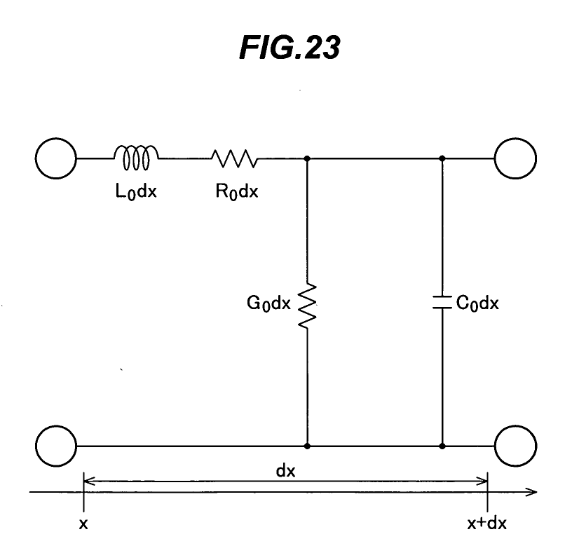

The constants derived above will now be used to calculate voltage and current values. For this purpose, a basic distributed constant circuit consisting of two parallel conductive lines disposed in parallel in a single plane will be considered. FIG. 23 shows an equivalent circuit of an infinitesimal segment of this basic distributed constant circuit. The x-axis in FIG. 23 is oriented in the longitudinal direction of the parallel conductive lines; dx is the length of the segment.

Kirchhoff's laws can be applied. If the resistance, inductance, conductance, and capacitance per unit length (1 m) are R₀, L₀, G₀, and C₀, respectively, then the corresponding quantities in the infinitesimal segment are R₀dx, L₀dx, G₀dx, and C₀dx, as indicated in FIG. 23. If the voltage and current at a point x on the x-axis are denoted V and I, respectively, and the voltage and current at a point x+dx are denoted V+dV and I+dI, respectively, the voltage and current satisfy the following equations (13-1), (13-2).

$$\begin{matrix}V - ( V + dV ) = {R}_{0} dx \cdot I + {L}_{0} \frac{d I}{d t} dx & ( 13 \text{-} 1 ) \\ I - ( I + dI ) = {G}_{0} dx \cdot V + {C}_{0} \frac{d V}{d t} dx & ( 13 \text{-} 2 )\end{matrix}$$

By rearranging these equations (13-1), (13-2), the following equations (14-1), (14-2) are obtained.

$$\begin{matrix}- \frac{d V}{d x} = {L}_{0} \frac{d I}{d t} + {R}_{0} I & ( 14 \text{-} 1 ) \\ - \frac{d I}{d x} = {C}_{0} \frac{d V}{d t} + {G}_{0} V & ( 14 \text{-} 2 )\end{matrix}$$

If the voltage V and current I are assumed to be given by V=V(x)·exp(jωt) and I=I(x)·exp(jωt) and these values are substituted into the above equations (14-1), (14-2), the following equations (15-1), (15-2) are obtained.

$$\begin{matrix}- \frac{d V}{d x} = ( {R}_{0} + j ϖ {L}_{0} ) I & ( 15 \text{-} 1 ) \\ - \frac{d I}{d x} = ( {G}_{0} + j ϖ {C}_{0} ) V & ( 15 \text{-} 2 )\end{matrix}$$

If these equations (15-1), (15-2) are differentiated with respect to x, the following equations (16-1), (16-2) are obtained.

$$\begin{matrix}- \frac{{d}^{2} V}{d {x}^{2}} = ( {R}_{0} + j ϖ {L}_{0} ) \frac{d I}{d x} & ( 16 \text{-} 1 ) \\ - \frac{{d}^{2} I}{d {x}^{2}} = ( {G}_{0} + j ϖ {C}_{0} ) \frac{d V}{d x} & ( 16 \text{-} 2 )\end{matrix}$$

Substitution of equations (16-1), (16-2) into equations (15-1), (15-2) gives the following equations (17-1), (17-2).

$$\begin{matrix}\frac{{d}^{2} V}{d {x}^{2}} = ( {R}_{0} + j ϖ {L}_{0} ) ( {G}_{0} + j ϖ {C}_{0} ) V & ( 17 \text{-} 1 ) \\ \frac{{d}^{2} I}{d {x}^{2}} = ( {R}_{0} + j ϖ {L}_{0} ) ( {G}_{0} + j ϖ {C}_{0} ) I & ( 17 \text{-} 2 )\end{matrix}$$

The solutions V(x), I(x) of these differential equations (17-1), (17-2) are given by the following equations (18-1), (18-2). x

V(x)=A exp(γx)+B exp(−γx) (18-1)

$$I ( x ) = \frac{I}{W} \{ - A exp ( γ x ) + B exp ( - γ x ) \} \qquad ( 18 \text{-} 2 )$$

In the above equations, A and B are integration constants determined by boundary conditions and W and γ are given by the following equations (19-1), (19-2).

$$W = \sqrt{\frac{{R}_{0} + j ϖ {L}_{0}}{{G}_{0} + j ϖ {C}_{0}}} \qquad ( 19 \text{-} 1 )$$

γ²=(R₀+j\tilde{ω}L₀)(G₀+j\tilde{ω}C₀)=(α+jβ)² 19-2)

The quantity γ, referred to as the propagation constant, has a real part α referred to as the attenuation constant and an imaginary part β referred to as the phase constant.

The real part a of the propagation constant γ is given by the following equation (20).

$${α}_{c} = \sqrt{\frac{1}{2} [ \sqrt{( {R}_{0}^{2} + {ϖ}^{2} {L}_{0}^{2} ) ( {G}_{0}^{2} + {ϖ}^{2} {C}_{0}^{2} )} + ( {R}_{0} {G}_{0} - {ϖ}^{2} {L}_{0} {C}_{0} ) ]} \qquad ( 20 )$$

The real part a of the propagation constant γ of the coplanar waveguide according to the invention is obtained by substituting the values of R and L given by equations (8-2) and (12) for R₀ and L₀ in equation (20). The conductance G₀ and the capacitance C₀ relate to the elements Gₛ, Cₛ, Cᵢ, and Cₐ in FIGS. 18 and 19.

The circuit portions including the elements Gₛ, Cₛ, Cᵢ, and Cₐ, shown in FIG. 19, may be expressed as parallel admittances, and the real and imaginary parts of these parallel admittances may be substituted for the conductance G₀ and the capacitance C₀, respectively.

Expressed as admittances, Cᵢ becomes jωCᵢ and the parallel elements Gₛ and Cₛ become Gₛ+jωCₛ. Their combined admittance is jωCᵢ(Gₛ+jωCₛ)/{Gₛ+jω)(Cₛ+Cᵢ)}. Since Cₐ is represented by the admittance jωCₐ, the total parallel admittance is given by the following equation (21).

$$γ = \frac{{ϖ}^{2} {G}_{s} {C}_{i}^{2} + j ϖ \{ {C}_{i} {G}_{s}^{2} + {ϖ}^{2} {C}_{i} {C}_{s} ( {C}_{i} + {C}_{s} ) \}}{{G}_{s}^{2} + {{ϖ}^{2} ( {C}_{s} + {C}_{i} )}^{2}} + j ϖ {C}_{a} \qquad ( 21 )$$

Accordingly, the conductance G₀ and capacitance C₀ in equation (20) are given by the following equations (22-1), (22-2).

$$\begin{matrix}{G}_{0} = \frac{{ϖ}^{2} {G}_{s} {C}_{i}^{2}}{{G}_{s}^{2} + {{ϖ}^{2} ( {C}_{s} + {C}_{i} )}^{2}} & ( 22 \text{-} 1 ) \\ {C}_{0} = \frac{\{ {C}_{i} {G}_{s}^{2} + {ϖ}^{2} {C}_{i} {C}_{s} ( {C}_{i} + {C}_{s} ) \}}{{G}_{s}^{2} + {{ϖ}^{2} ( {C}_{s} + {C}_{i} )}^{2}} + {C}_{a} & ( 22 \text{-} 2 )\end{matrix}$$

The value of the real part α_{c} of the propagation constant γ given by equation (20) is expressed in nepers per meter (Np/m), which can be converted to decibels per meter (dB/m) by multiplying by 20/ln(10).

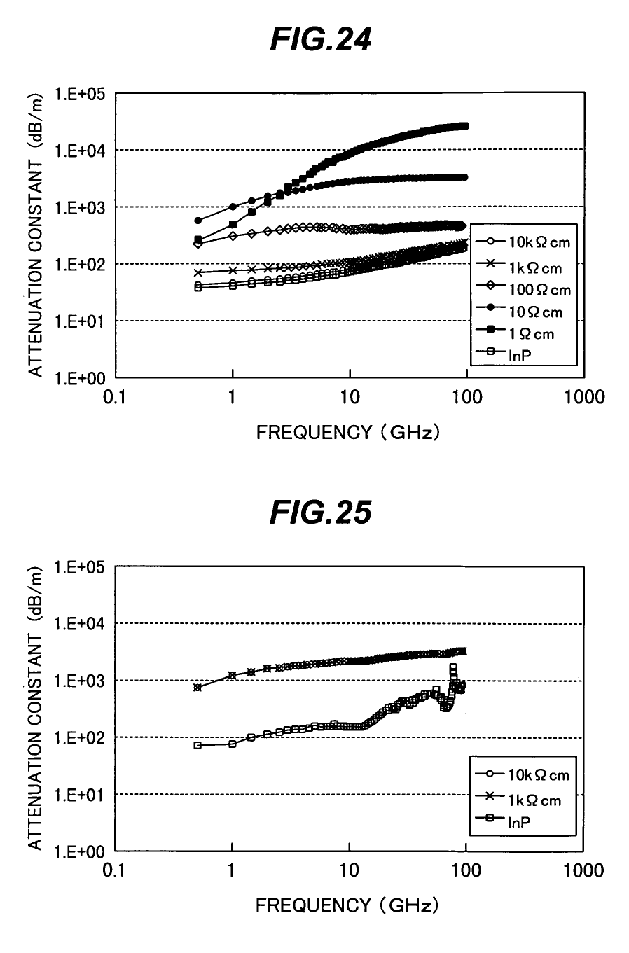

The attenuation constant α_{c} of the coplanar waveguide derived from the equivalent distributed constant circuit as described above has the frequency dependency shown in FIG. 24. The calculations were performed on the assumption that an SiN film was deposited uniformly on a silicon substrate and a gold (Au) coplanar waveguide was formed on the SiN film. The resistivity ρ of gold was taken to be 2.4×10⁻⁸ Ω·m, the width w of the signal line was taken to be 16 μm, the distance G between the signal line and the ground conductors was taken to be 12 μm, the thickness of the signal line was taken to be 4 μm, the relative permittivity of silicon was taken to be 11.9, the relative permittivity of SiN was taken to be 6.5, and the thickness of the SiN film was taken to be 200 nm.

The calculations were repeated under differing assumptions for the resistivity of the silicon substrate: 10 kΩ·cm (indicated by white circles), 1 kΩ·cm (indicated by cross marks), 100 Ω·cm (indicated by white diamond marks), 10 Ω·cm (indicated by black circles), and 1 Ω·cm (indicated by black squares). For comparison, the calculations were also performed for an InP substrate (indicated by white squares) with an assumed resistivity of 1×10⁷ Q·m.

The results shown in FIG. 24 indicate that when the resistivity of the silicon substrate is 1 to 10 kΩ·cm, the attenuation constant is as low as with an InP substrate. At a frequency of 1 GHz, for example, the 1 kΩ·cm and 10 kΩ·cm silicon substrates and InP substrate show an attenuation constant of 100 dB/m or less, whereas the 1 Ω19 cm, 10 Ω·cm, and 100 Ω·cm silicon substrates show attenuation constants greater than 300 dB/m. At a frequency of 10 GHz, the InP substrate shows an attenuation constant of about 70 dB/m, and the 1 kΩ·cm and 10 kΩ·cm silicon substrates show an attenuation constant of about 100 dB/m, which is on the same order of magnitude, but the 100 Ω·cm silicon substrate shows an attenuation constant of 400 dB/m and the 1 Ω·cm and 10 Ω·cm silicon substrates show attenuation constants of 2000 dB/m or more, which is an order of magnitude greater than the attenuation constant of the InP substrate.

Coplanar waveguides were fabricated under the conditions assumed in the above calculations and their attenuation constants were measured, giving the results shown in FIG. 25. As shown in FIG. 25, when the substrate resistivities were 1 kΩ·cm and 10 kΩ·cm, for example, the attenuation constants exceeded 1000 dB/m at a frequency of 1 GHz and reached 2000 dB/m at a frequency of 10 GHz. These measured attenuation constants greatly exceeded the calculated values. Although the so-called tanδ dielectric loss effect was not considered in the above calculations, the discrepancy is too large to be explained by this effect alone. A similar discrepancy was observed when the insulating film was an SiO₂ film.

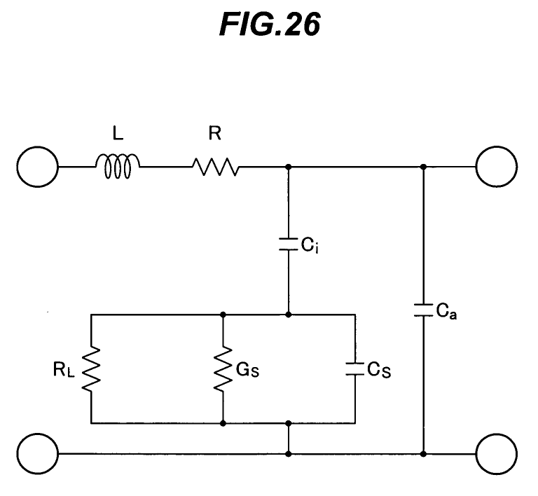

The discrepancy can be explained by assuming that a low-resistivity layer is formed at the interface between the SiN insulating film and the silicon substrate, as indicated by the equivalent circuit diagram shown in FIG. 26. The resistance component R_{L} of the low-resistivity layer is in parallel with the conductance Gₛ.

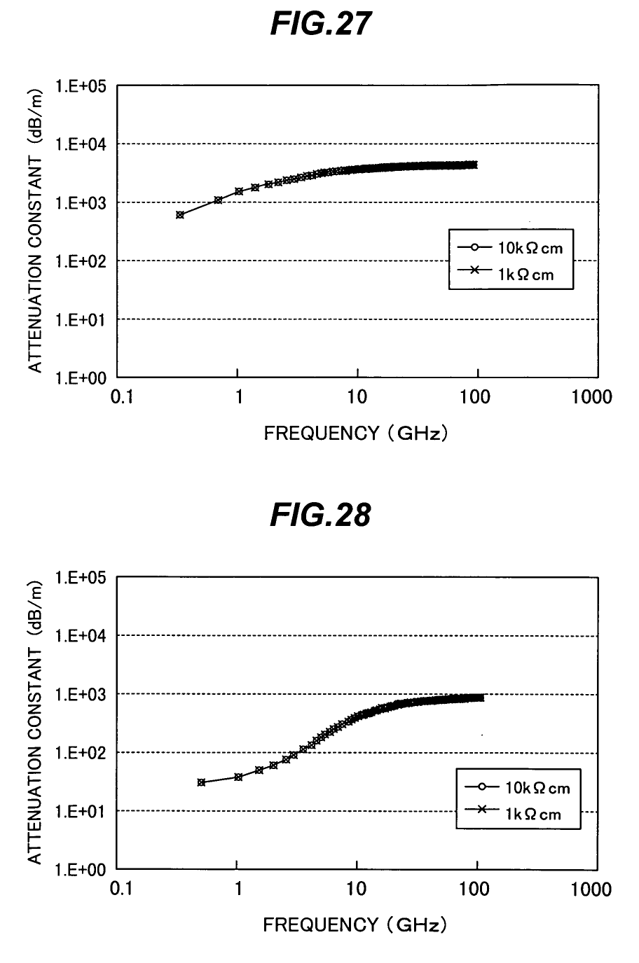

FIG. 27 shows the results of calculations of the attenuation constant that included this low-resistivity layer. For silicon substrate resistivities of both 1 kΩ·cm and 10 kΩ·cm, the attenuation constant was about 1000 dB/m at a frequency of 1 GHz and about 2700 dB/m at a frequency of 10 GHz, reproducing the measurement results shown in FIG. 25.

The reason for these elevated attenuation constants is thought to be that electromagnetic waves propagating along the signal line leak through the low-resistivity layer to the ground conductors. If this assumption is correct, it is possible to mitigate the effect of the low-resistivity layer by increasing the thickness of the insulating film to about 10 μm. This is borne out by FIG. 28, which shows the results of calculations of the attenuation constant when the low-resistivity layer is assumed to be present and the insulating film is 10 μm thick.

The above discussion indicates that a low-resistivity layer produced at the interface between a high-resistivity silicon substrate and an insulating film causes the attenuation constant of a coplanar waveguide to increase. In the coplanar waveguide according to the invention, since the insulating film is removed by etching between the signal and ground conductors, the low-resistivity layer is eliminated in these regions, interrupting the low-resistance path indicated by R_{L} in FIG. 26. As a result, a coplanar waveguide can be obtained that is capable of operating in the millimeter-wave frequency band, as indicated by the 1-kΩ·cm and 10-kΩ·-cm curves in FIG. 24.

Several variations of the novel coplanar waveguide have been shown above, but those skilled in the art will recognize that further variations are possible within the scope of the invention, which is defined in the appended claims.

What is claimed is:

1. A coplanar waveguide comprising:
a substrate having a major surface;
a signal line formed on the substrate;
a pair of ground conductors formed on the major surface of the substrate on mutually opposite sides of the signal line;
a signal line insulating film disposed between the signal line and the substrate; and
a ground conductor insulating film disposed between the pair of ground conductors and the substrate.

2. The coplanar waveguide of claim 1, wherein the signal line insulating film and the ground conductor insulating film are at least two hundred nanometers thick but not more than two micrometers thick.

3. The coplanar waveguide of claim 1, wherein the signal line insulating film and the ground conductor insulating film are films of silicon oxide, silicon nitride, or silicon oxynitride.

4. The coplanar waveguide of claim 1, wherein the signal line insulating film and the ground conductor insulating film have a stacked structure including a silicon oxide film and a silicon nitride film, or a silicon oxynitride film and a silicon nitride film.

5. The coplanar waveguide of claim 1, wherein the substrate is a silicon substrate.

6. The coplanar waveguide of claim 1, wherein the silicon substrate has a resistivity greater than one hundred ohm-centimeters.

7. The coplanar waveguide of claim 1, wherein trenches are formed on the major surface of the substrate between the signal line and the ground conductors.

8. The coplanar waveguide of claim 7, further comprising at least one conductive bridge interconnecting the pair of ground conductors, the conductive bridge passing over the signal line.

9. The coplanar waveguide of claim 7, wherein the trenches have a depth of at least two hundred nanometers.

10. A method of fabricating a coplanar waveguide, comprising:
forming an insulating film on a major surface of a substrate;
forming a signal line and a pair of ground conductors on the insulating film, the signal line being formed between the ground conductors; and
removing the insulating film between the signal line and the ground conductors using the signal line and the ground conductors as a mask.

11. The method of claim 10, wherein the insulating film has a thickness of at least two hundred nanometers but not more than two micrometers.

12. The method of claim 10, wherein the insulating film is a film of silicon oxide, silicon nitride, or silicon oxynitride.

13. The method of claim 10, wherein the insulating film is formed as a stacked structure including a silicon oxide film and a silicon nitride film, or a silicon oxynitride film and a silicon nitride film.

14. The method of claim 10, wherein the substrate is a silicon substrate.

15. The method of claim 14, wherein the silicon substrate has a resistivity greater than one hundred ohm-centimeters.

16. The method of claim 14, further comprising forming trenches on the major surface of the substrate between the signal line and the ground conductors after removing the insulating film between the signal line and the ground conductors.

17. The method of claim 16, further comprising forming at least one conductive bridge interconnecting the pair of ground conductors, the conductive bridge passing over the signal line.

18. The method of claim 16, wherein the trenches have a depth of at least two hundred nanometers.
